(19) United States
(12) Patent Application Publication
(10) Pub. No.: US 2002/0064605 A1
(43) Pub. Date: May 30, 2002

(54) Method of coating a substrate and vane for vane-type compressor

(76) Inventors: Kiyoharu Hatakenaka, Osaka (JP); Naoyuki Omori, Osaka (JP)

Correspondence Address: OPPENHEIMER WOLFF & DONNELLY, P. O. BOX 10356, PALO ALTO, CA, 94303, US

(21) Appl. No.: 09/858,296

(22) Filed: May 15, 2001

(30) Foreign Application Priority Data
Oct. 11, 2000 (JP) 2000-310086

(51) Int. Cl. C23C 14/32; C23C 14/00; F04D 29/00

(52) U.S. Cl. 427/523; 415/148; 427/524; 427/530; 134/1.1; 204/192.15; 204/192.16; 204/192.3

(57) ABSTRACT

A method of coating a substrate includes the step of forming a chrome layer on the substrate by using a magnetron sputtering device, and the step of forming a chrome nitride layer on the chrome layer by using an arc type ion plating device while maintaining the temperature of the substrate between 100 and 200° C. A vane used for a vane-type compressor, which is subjected to a surface treatment according to the coating method of the present invention is also provided.

### BACKGROUND OF THE INVENTION

1. Field of the Invention

The present invention relates to a surface treating technique for coating a substrate, namely a varying mechanical element with a film including a chrome nitride (hereinafter referred to CrN) layer, which technique is suitable for the surface treatment of, for example, vanes in a vane-type compressor adapted for compressing gasses such as cooling gas.

2. Discussion of the Background

Since CrN forms a very hard surface with a surface hardness (Hv) of 1800, and a relatively high slidability, it is employed as a coating material for a substrate and more particularly a mechanical element which is used under severe sliding conditions. An ion plating method of an HCD (Hollow Cathode Discharge) type, arc discharge type or the like is commonly employed to coat the substrate with that material.

The above methods are however disadvantageous in the fact that, where the substrate is maintained at a low temperature during the surface treatment by the above coating methods, the coated material exhibits poor durability or poor adhesive to the substrate, rendering the substrate intolerable against actual use. To overcome this problem, it is necessary to heat the substrate to a high temperature of not less than 450° C. for the surface treatment. However, where the substrate (e.g., alloy steel and SC steel) subjected to this surface treatment at a high temperature is annealed at about 150 to 200° C., its mechanical properties may be varied or subjected to thermal damage. Therefore, in the conventional surface treatment technique, the materials used for the substrate are necessarily limited to such as high speed tool steels whose annealing temperature ranges from about 520 to 570° C.

In consideration of the above problem, it is an object of the present invention to provide a method of coating a substrate without the necessity of limiting the material of the substrate, and more specifically the method that can prevent the deterioration of the mechanical properties of the heated substrate.

### SUMMARY OF THE INVENTION

According to a first aspect of the present invention, there is provided a method of coating a substrate that includes the step of forming a chrome (hereinafter referred to Cr) layer on the substrate by using a magnetron sputtering device, and the step of forming a CrN layer on the Cr layer by using an arc type ion plating device while maintaining the temperature of the substrate between 100 and 200° C.

According to a second aspect of the present invention, there is provided a method of coating a substrate that includes the step of forming a Cr layer on the substrate by using a magnetron sputtering device, and the step of forming a CrN layer on the Cr layer by using a magnetron sputtering device.

According to a third aspect of the present invention, there is provided a method of coating a substrate that includes the step of forming a Cr layer on the substrate by using a magnetron sputtering device, and the step of forming a CrN layer on the Cr layer by using an unbalanced magnetron (hereinafter referred to UBM) sputtering device.

In any one of the methods according to the present invention, the first step involves the formation of the Cr layer on the substrate set within the magnetron sputtering device by using the same. The magnetron sputtering device is of the type that has a magnet disposed on the rear side of a target set on a position facing a substrate set within the device, thereby applying a magnetic field to confine electrons within a space in proximity with the target. With this arrangement, a plasma generated within the device is concentrated into the space in proximity with the target, so that damages against the substrate through the electrons or the plasma can be reduced, while preventing the temperature rise of the substrate. Accordingly, it is unlikely to cause the thermal damage against the substrate during this step.

It is preferable to perform a plasma-etching step prior to the step of forming the Cr layer. The plasma-etching process involves the formation of the plasma from argon (hereinafter referred to Ar) gas introduced for the processing, and the removal of oxide film, water or oil from the surface of the substrate through Ar ions. Through this processing, the adhesive of the Cr layer to the surface of the substrate can be improved.

The Cr layer acts as an intermediate layer between the substrate and the CrN layer, so that the Cr layer is required to possess not only a sufficient adhesive against the surface of the substrate, but also a certain degree of flexibility. In a conventional magnetron sputtering device, the bias voltage is generally set in the range of −20 to −30 Volts. In this regard, the inventors of the present invention have found that a more preferable result can be produced by setting the bias voltage at 0 Volts. The setting the bias voltage at 0 Volts can prevent excessive hardness of the Cr layer and hence poor adhesive of the Cr layer due to the residual inner stress in the Cr layer's, which inner stress is accompanied by the increase of the hardness. The thickness of the Cr layer is preferably set in the range of 0.1 to 1.0 μm and more particularly in the range of 0.1 to 0.5 μm.

According to the first, second and third aspects of the present invention, the step subsequent to the above Cr layer formation step involves the formation of the CrN layer on the Cr layer formed on the surface of the substrate by respectively using the arc type ion plating device, the magnetron sputtering device and the UBM sputtering device.

The arc type ion plating device is of the type that vaporizes a plating material (i.e., Cr in this case) and then ionizes the same through an arc discharge, then accelerates the ionized plating material by the addition of an electric field thereto, and then deposits the plating material (Cr reacted with nitrogen gas) on the surface of the substrate (the surface of the Cr layer). In the first aspect of the present invention, it is critical to maintain the temperature of the substrate set within the device between 100 and 200° C. and more preferably 130 and 180° C. The temperature of the substrate lying in these ranges is closer to the heat treatment temperature (annealing temperature) of the substrate. Hence, the substrate is unlikely to be heated to an excessively high temperature under such temperature control, so that the thermal damage can be avoided. Moreover, since the Cr layer acting as a ground coat for the CrN layer is formed on the substrate, and the CrN layer possesses a good adhesion against the Cr layer (60 to 80N in Lc value), the CrN layer is unlikely to delaminate from the Cr layer.

In the second aspect of the present invention, the magnetron sputtering device is unlikely to cause thermal damage on the substrate when forming the CrN layer on the Cr layer as with the prior step of forming the Cr layer on the substrate. In the third aspect of the present invention, the UBM sputtering device not only produces an effect of preventing the substrate from receiving the thermal damage, but also exhibits a faster film forming performance as compared with the magnetron sputtering device, which results in an improved productivity and reduced manufacturing costs. The UBM sputtering device is of the type that includes several magnets, which have different magnetic properties at a center region and a peripheral region of a rounded target, and are arranged to have magnetic fields linked with the adjacent fields to form a closed and strong magnetic field whose magnetic fluxes partly reaches the proximity of the substrate, thereby allowing plasma constituents to be condensed at the substrate. In any one of the aspects of the present invention, a good adhesion (60 to 80N in Lc value) is obtainable.

The CrN layer preferably has 0.5 to 5 μm in thickness and more preferably 1 to 2 μm for improved wear resistance.

### DETAILED DESCRIPTION OF THE PREFERRED EMBODIMENT

### First Embodiment

Initially, a case hardening alloy steel, JIS SCM415 was pressed into vanes used for a vane-type compressor. After that, they were carburized to modify the surface of each vane. The vane-type compressor generally includes a cylinder block having a circular or oval shaped internal cylinder whose both sides have side plates fixed thereon to make up a compressor body with a rotor disposed therein, and a plurality of vane slots formed on either the rotor or the cylinder block, through which the vanes radially extend in a retractable manner. According to this arrangement, the rotor is rotated with the vanes being pressed against the inner circumferential surface of the cylinder block or the outer circumferential surface of the rotor. Whereby, a gas within compression compartments between the vanes is compressed.

Subsequent to the above, the substrate is subjected to the plasma etching under the following plasma etching treatment condition:

Plasma source current: 35A

Etching voltage: 200 V

Ar flow rate: 65 sccm

Vessel inner pressure: 1×10⁻³ mbar

Processing time: 30 min

Next, the substrate is subjected to the Cr coating under the following coating condition:

Operation type: Magnetron sputtering

Sputtering power: 8 kW

Ar flow rate: 225 sccm

Bias voltage: 0 V

Vessel inner pressure: 3×10⁻³ mbar

Processing time: 10 min

Next, the substrate is subjected to the CrN coating under the following coating condition:

Operation type: Arc type ion plating

Arc current: 160 A×2 targets

Nitrogen gas flow rate: 1000 sccm

Bias voltage: 20 V

Vessel inner pressure: 2×10⁻² mbar

Processing time: 30 min×4 times with intervals of 15 min

With this intermittent operation, the temperature rise of the substrate can be limited to below 180° C.

It is to be noted that the respective processes, namely plasma-etching process, Cr coating process and CrN coating process can be performed by using different devices, or performed intensively by a single device having multiple functions.

### Second Embodiment

In this embodiment, the Cr coating process and previous processes thereto are carried out in the same manner as that of the first embodiment, while the process for forming the CrN coating employs a different coating condition as stated below:

Operation type: Unbalanced magnetron sputtering

Sputtering power: 5 kW

Ar flow rate: 165 sccm

Nitrogen gas flow rate: 60 sccm

Bias voltage: 300 V

Vessel inner pressure: 3×10⁻³ mbar

Processing time: 120 min

### Comparative Example

The CrN coating process was performed in the arc type ion plating device by using the substrate of the same material as those in the first and second embodiments. The processing condition was varied in four patterns with the substrate temperatures of 180° C., 250° C., 350° C. and 450° C., which patterns were respectively designated as the comparative examples 1 to 4.

With respect to the coats formed in the first and second embodiments and the comparative examples 1 to 4, the thickness, the hardness and the adhesion (scratch critical load) of each coat were respectively measured by using an electron micrograph, a microvickers hardness tester and a scratch tester. Then, the impact resistance test was conducted by using a hammer tester of the inventor's own making having a hammer curvature of 22.5, 30 Hz and 0.2 MPa. The test results obtained are shown in Table 1.

TABLE 1

| | | | | | | Hardness |
|---|---|---|---|---|---|---|
| | | Coating | | | | of a base |
| | Temperature | thickness | Hardnes | Adhesion | | material |
| | (°C.) | (μm) | s (Hv) | (N) | Impact test result | (HRC) |
| Embodiment 1 | 180 | 2.6 | 1862 | 72 | No observation of | 61 |
| | | | | | coat destruction | |
| Embodiment 2 | 180 | 2.7 | 1882 | 78 | No observation of | 61 |
| | | | | | coat destruction | |
| Comparative | 180 | 2.5 | 1800 | 25 | Coat delamination | 61 |
| Example 1 | | | | | and falling | |
| Comparative | 250 | 2.5 | 1800 | 35 | Coat delamination | 58 |
| Example 2 | | | | | and falling | |
| Comparative | 350 | 2.6 | 1800 | 55 | Coat delamination | 52 |
| Example 3 | | | | | and falling | |
| Comparative | 450 | 2.5 | 1800 | 75 | No observation of | 45 |
| Example 4 | | | | | coat destruction | |

As being understandable from the above table, particularly from the values of the hardness of each base material, the comparative examples 2 to 4 received thermal damage, and therefore cannot be utilized as commercial products. The comparative example 1 did not receive thermal damage, but exhibits poor adhesion and impact resistance property as compared with the first and second embodiments. Therefore, the comparative example 1 cannot also be utilized as a commercial product.

The compressor, into which the first embodiment was incorporated, was operated for 48 hours at a high pressure of 33.0 kg/cm² and at a discharge temperature of 117° C., using a refrigerant of R22. The test results are shown below:

Wear amount of the tip portion of a vane: 0 μm

Wear amount of the vane suction side: 0 μm

Wear amount of the vane discharge side: 0 μm

Wear amount of the cylinder suction side: 3.5 μm

Wear amount of the cylinder discharge side: 0.2 μm

Wear amount of the piston periphery: 0.5 μm

From the above results, it has been found that the first embodiment exhibits excellent wear resistance property or slide resistance property, and hence can be used as a commercial product which is tolerable against actual use. The same effects can undoubtedly be expected for the second embodiment.

As described above, the surface treatment of the present invention as mentioned above can obtain a preferable coating, while preventing the deterioration of the mechanical properties of the substrate. Accordingly, the material of the substrate is not limited to the case-hardening alloy steel exemplified herein by the SCM415 only. Rather, SC steels such as JIS S45C, carbon tool steels such as JIS SK5, high speed tool steels such as JIS SKH51, alloy steels for entire quench hardening such as JIS SCM435, alloy tool steels such as SKD11, cold rolled steel plates sheet and strip in cut length such as JIS SPCC, hot rolled mild steel plates sheet and strip in cut length such as JIS SPHC, aluminum base alloys, brass, bronze or the like can be used as the material of the substrate. Among these materials, the SK5, the SKH51 and the SKD11 are subjected to the heat treatment by quench hardening. Also, the SCM435 is subjected to nitriding treatment, while the SPCC and the SPHC are subjected to carbonitriding treatment.

As one of the features of the present invention, the temperature of the substrate is maintained between 100 and 200° C. in the arc type ion plating device to prevent the thermal damage caused on the substrate due to the excessive heating of the substrate over the temperature for the heat treatment. Therefore, for the SC steels such as the S45C, the carbon tool steels such as the SK5, the hot rolled mild steel plates sheet and strip in cut length such as the SPHC, or other material, which are heat-treated at a relatively high temperature, there causes less problem even if the substrate of these materials is heated at a temperature of 100 to 380° C.

The coating method of the present invention is not necessarily limited to the coating of the vanes of the compressor. Rather, it is applicable to various mechanical elements such as rotor, piston, crank shaft, cylinder, etc., in a compressor, cam, shaft, needle, sinker, etc., in a sewing machine, cam, cam shaft, crank shaft, valve lifter, shim, etc., in an automobile engine, and various other mechanical elements.

It has been found that a TiN, TiCN, or TiAlN coating as an alternative to the CrN coating of this embodiment can also produce the same effect. For example, the TiN layer is coated on the Cr layer, which coating process was performed under the following conditions and produced the following results. In this respect, the TiN, TiCN or TiAlN coating method, and the TiN, TiCN or TiAlN layer forming method in each of the arc type ion plating device, the magnetron sputtering device and the unbalanced magnetron sputtering device are known, so that the detailed descriptions thereof will be omitted.

Conditions:

Operation type: Arc type ion plating

Arc current: 160 A×2 targets

Nitrogen gas flow rate: 1000 sccm

Bias voltage: 20 V

Vessel inner pressure: 2×10⁻² mbar

Processing time: 30 min×4 times with intervals of 15 min

Results:

Processing temperature: 180° C.

Coating thickness: 2.6 μm

Coating hardness: 2230 Hv

Adhesion: 65 N

Impact test: No coat destruction was observed

Hardness of a base material: HRC 61

It has also been found that, alternative to the Cr coating of this embodiment, a Ti coating can produce the same effect. Specifically, it is also useful that the coating method includes the step of forming a titanium layer on the substrate by using the magnetron sputtering device, and the step of forming a chrome nitride, titanium nitride, titanium carbonitride, or titanium-aluminum nitride layer on the titanium layer by using the arc type ion plating device, magnetron sputtering device or the unbalanced magnetron sputtering device.

As described above, according to the method of the present invention, the processing temperature or the temperature of the substrate is hardly increased to a higher temperature unlike the arc type or HCD type ion plating method, so that there is no room for the thermal damages of the substrate. Consequently, it is not necessary to limit the material of the substrate to a specific one. Therefore, where the SPHC, which is less expensive and easy for press working, is selected as the substrate, it is possible to provide the entire mechanical elements including such as vanes of the compressor, in a relatively cheap manner.

This specification is by no means intended to restrict the present invention to the preferred embodiments set forth therein. Various modifications to the method of coating a substrate and vane for vane-type compressor, as described herein, may be made by those skilled in the art without departing from the spirit and scope of the present invention as defined in the appended claims.

What is claimed is:

1. A method of coating a substrate comprising:
the step of forming a chrome layer on the substrate by using a magnetron sputtering device; and
the step of forming a chrome nitride layer on said chrome layer by using an arc type ion plating device while maintaining the temperature of said substrate between 100 and 200° C.

2. A method of coating a substrate according to claim 1, wherein the bias voltage is set at 0 Volts during the step of forming the chrome layer.

3. A method of coating a substrate according to claim 1, wherein the thickness of the chrome layer is set in the range of 0.1 to 1.0 μm.

4. A method of coating a substrate according to claim 1, wherein the thickness of the chrome nitride layer is set in the range of 0.5 to 5 μm.

5. A method of coating a substrate according to claim 1, further comprising a plasma-etching step prior to the step of forming the chrome layer to remove oxide film, water or oil from the surface of the substrate.

6. A method of coating a substrate comprising:
the step of forming a chrome layer on the substrate by using a magnetron sputtering device; and
the step of forming a chrome nitride layer on said chrome layer by using a magnetron sputtering device.

7. A method of coating a substrate according to claim 6, wherein the bias voltage is set at 0 Volts during the step of forming the chrome layer.

8. A method of coating a substrate according to claim 6, wherein the thickness of the chrome layer is set in the range of 0.1 to 1.0 μm.

9. A method of coating a substrate according to claim 6, wherein the thickness of the chrome nitride layer is set in the range of 0.5 to 5 μm.

10. A method of coating a substrate according to claim 6, further comprising a plasma-etching step prior to the step of forming the chrome layer to remove oxide film, water or oil from the surface of the substrate.

11. A method of coating a substrate comprising:
the step of forming a chrome layer on the substrate by using a magnetron sputtering device; and
the step of forming a chrome nitride layer on said chrome layer by using an unbalanced magnetron sputtering device.

12. A method of coating a substrate according to claim 11, wherein the bias voltage is set at 0 Volts during the step of forming the chrome layer.

13. A method of coating a substrate according to claim 11, wherein the thickness of the chrome layer is set in the range of 0.1 to 1.0 μm.

14. A method of coating a substrate according to claim 11, wherein the thickness of the chrome nitride layer is set in the range of 0.5 to 5 μm.

15. A method of coating a substrate according to claim 11, further comprising a plasma-etching step prior to the step of forming the chrome layer to remove oxide film, water or oil from the surface of the substrate.

16. A vane used for a vane-type compressor characterized by that it is subjected to a surface treatment according to a coating method of any one of claims 1 to 15.
